(19) United States
(12) Patent Application Publication
(10) Pub. No.: US 2023/0239999 A1
(43) Pub. Date: Jul. 27, 2023

(54) RF DISTRIBUTION VOLUME AND ELECTRONIC DEVICE

(71) Applicants: EV-TECHNOLOGIES, COLOMBELLES (FR); EUROPEAN ENGINEERING & CONSULTANCY LIMITED, Kingston-Upon-Thames (GB)

(72) Inventors: Sidina WANE, CAEN (FR); Benjamin Ian KIENIEWICZ, KINGSTON-UPON-THAMES (GB)

(21) Appl. No.: 17/999,825

(22) PCT Filed: May 28, 2021
(86) PCT No.: PCT/EP2021/064456

§ 371 Date: Nov. 23, 2022

(30) Foreign Application Priority Data
May 28, 2020 (EP) 20305558.7

(51) Int. Cl. H05K 1/02; H05K 1/05; G01R 1/24

(52) U.S. Cl. CPC H05K 1/0243; G01R 1/24; H05K 1/05; H05K 2201/10098; H05K 2201/10151; H05K 2201/10356

(57) ABSTRACT

The present disclosure relates to an electronic device (10) comprising at least one electrically conductive structure (11) with a tubular shape having outer and inner surfaces (11c, 11d) covered by an insulating layer (12), and one or more integrated circuits (13) positioned within the electrically conductive structure (11).

The present patent application claims priority from the European patent application filed on 28 May 2020 and assigned application no. EP20305558.7, the contents of which is hereby incorporated by reference.

### TECHNICAL FIELD

The present disclosure relates generally to the field of electronic devices, and in particular to electronic devices conducting frequencies in the upper RF (Radio Frequency) or millimeter wave ranges.

### BACKGROUND ART

The automatized testing and validation of 5G (Fifth Generation) and IoT (Internet of Things) communication devices requires appropriate instruments capable, for example, of evaluating power integrity (PI), signal integrity (SI), and conformity with EMC (Electro-Magnetic Capability) and EMI (Electro-Magnetic Interference) specifications. Indeed, PI, SI, EMC and EMI performance is a critical issue for new generation communications systems that are required to have very high data transmission rates, low energy consummation, and a strong immunity to undesirable disturbances.

Near-field sensing of the emissions of circuits and systems having integrated antennas provides a mechanism to verify EMC/EMI conformity, perform OTA (Over The Air) testing and perform diagnosis of EMC/EMI and power and signal integrity problems.

A solution for such automatized testing and validation can be to use a probe array in order to characterize at least part of a DUT (Device Under Test). However, a difficulty with such a solution is to perform precise and effective high sensitivity sensing via the probes of the array when the frequencies involved can be in the upper RF (Radio Frequency) or millimeter wave ranges. Another difficulty is that the DUT may be a 3D surface, which prevents the use of classical probing solutions.

### SUMMARY OF INVENTION

It is an aim of the present disclosure to at least partially address one or more needs in the prior art.

One embodiment provides an electronic device comprising at least one electrically conductive structure with a tubular shape having outer and inner surfaces covered by an insulating layer, and one or more integrated circuits positioned within the electrically conductive structure.

According to one embodiment, the electronic device is comprising a plurality of said electrically conductive structure.

According to one embodiment, the said electrically conductive structure is at least partly made of metal.

According to one embodiment, said electrically conductive structure and the insulating layer of the inner and outer surface of the electrically conductive structure comprise at least a first and a second portion arranged to assume sequentially a first configuration where the first and second portions are attached together and a second configuration where the first and second portions are separated in such way that the integrated circuit is accessible.

According to one embodiment, the first and second portions comprise a layer of a magnetic material for attaching the first and second portions together.

According to one embodiment, the insulating layer is positioned between the electrically conductive structure and at least a part of one or more conducting wires extending inside the electrically conductive structure.

According to one embodiment, the insulating layer covering the outer surface of the electrically conductive structure is made of a selective laser sintering material, such as nylon or polyamide.

According to one embodiment, the insulating layer covering the outer surface of the electrically conductive structure comprises one or more distributed antenna pads mounted thereon, each distributed antenna pad being electrically coupled to at least one of the one or more integrated circuits.

According to a further aspect, there is provided a method of manufacturing an electronic device, such as the electronic device of the previous embodiment, the method comprising:
providing one or more integrated circuits;
forming an insulating layer surrounding at least a part of the one or more integrated circuits; and
forming an electrically conductive structure with a tubular shape in such a way that the insulating layer covers an inner surface and an outer surface of the electrically conductive structure.

According to yet a further aspect, there is provided an RF signal distribution device, comprising:
a main body having a first surface and a second surface opposed to the first surface; and
a plurality of tunnels extending across the main body from the first surface to the second surface, each tunnel having a first end arranged on the first surface and a second end arranged on the second surface;
wherein the first ends of the tunnels are spaced from each other according to a first surface distribution, the second ends of the tunnels are spaced from each other according to a second surface distribution different from the first surface distribution; and
an inner surface of each tunnel forms an electrically conductive structure.

According to one aspect, the RF signal distribution is further comprising an insulating layer being positioned between the electrically conductive structure of each tunnel and at least part of one or more integrated circuits positioned within each tunnel of the plurality.

According to one aspect, the insulating layer is positioned between the electrically conductive structure and at least a part of one or more conducting wires extending inside each electrically conductive structure.

According to one aspect:
the first surface distribution has a first regular pitch arrangement; and
the second surface distribution has a second regular pitch arrangement different from the first regular pitch arrangement.

According to one aspect, the main body is made of a material chosen between an insulator, a plastic, a metal, a selective laser sintering material, and a stacking of different layers of printed circuit board.

According to yet another aspect, there is provided a method of manufacturing an RF signal distribution device, comprising:
preparing, in a main body having a first surface and a second surface, a plurality of tunnels extending across the main body from the first surface to the second surface, each tunnel having a first end arranged on the first surface and a second end arranged on the second surface;
an inner surface of each tunnel forming an electrically conductive structure;
the first ends of each of the tunnels being spaced from each other according to a first surface distribution;
the second ends of each of the tunnels being spaced from each other according to a second surface distribution different from the first space distribution.

According to one aspect, the plurality of tunnels in the main body are obtained with either a selective laser sintering process, a molding process, a 3D printing process or a stacking of a plurality of printed circuit board layers.

According to one aspect, the plurality of tunnels and the corresponding electrically conductive structures are formed by stacking of a plurality of printed circuit boards.

According to one aspect, the method is comprising:

positioning or forming an insulating layer at least between the said electrically conductive structure of each tunnel and at least part of one or more integrated circuits positioned within each electrically conductive structure.

According to one aspect, the method is comprising:

positioning or forming the insulating layer between the electrically conductive structure of each tunnel and at least part of one or more conducting wire running inside each electrically conductive structure.

According to one aspect, the method is comprising:

forming or positioning the electronic device within each electrically conductive structure.

According to one aspect, at least one first conducting wire of the one or more conducting wires is coupled to the one or more integrated circuits, and is adapted to:
transport a first RF signal from a first end of the first conducting wire to the one or more integrated circuits to which it is coupled; and
transport a second RF signal from said one or more integrated circuits to a second end of the corresponding first conducting wire.

According to one aspect, an RF connector has at least a first pin electrically coupled to the electrically conductive structure.

According to one aspect, each RF connector has at least a second pin coupled to either the corresponding first or second end of the first conductive wire.

According to one aspect, the one or more integrated circuits are adapted to provide impedance adapting.

According to one aspect, at least one further conducting wire is running inside each electrically conductive structure, the at least one further conducting wire being coupled to the one or more integrated circuits and providing to the said integrated circuit one or more of:
a supply voltage;
a control signal;
a reset signal; and
a bypass signal.

According to one aspect, the integrated circuit is one of:
an RF circuit coupled to one or more antennas; or
an RF transceiver.

According to one aspect, the RF circuit is coupled to a plurality of antennas capable of beam forming.

According to one aspect, the integrated circuit comprises a wireless communication device arranged to:
receive data for controlling the said integrated circuit; and/or
transmit, to an external device such as another electronic device 10, data related to the integrated circuit or to the first and/or second signals.

According to one aspect, the electrically conductive structure has a cross-section width or diameter of at least 300 µm and for example of at least 1 mm, and/or of less than 5 mm, for example of substantially 5 mm, of substantially 2.5 mm or of substantially 1 mm.

According to one aspect, the electrically conductive structure is coupled to a ground voltage.

According to one aspect, the electronic device or the RF signal distribution device or the method, further comprising one or more energy harvesting devices positioned within the electrically conductive structure and coupled to the one or more integrated circuits and/or integrated within at least one of the integrated circuits.

According to yet a further aspect, there is provided an RF signal distribution system comprising:
the such RF signal distribution device;
a sensor or antenna array where at least part of the sensors or the antennas of the sensor or antenna array are arranged with a distribution similar to the first surface distribution of the RF signal distribution device ;
a switching matrix with a two-dimensional array of input/output nodes, the two-dimensional array being similar to the second surface distribution of the RF signal distribution device; wherein:
   the RF signal distribution device is arranged between the sensor or antenna array and the switching matrix in such way that:
   each sensor or antenna of the sensor or antenna array is electrically coupled to the first end of the first conducting wire of one of the electrically conductive structure of the RF signal distribution device; and each of the input/output nodes is electrically coupled to the second end of the said first conducting wire.

According to one aspect, each sensor or antenna of the sensor or antenna array is aligned with a corresponding first end of one of the tunnels of the RF signal distribution device; and

the input/output nodes of the two-dimensional array are aligned each with the second end of the corresponding tunnel.

According to yet another aspect, there is provided an RF signal distribution apparatus comprising:
a plurality of such electronic devices;
a sensor or antenna array where at least part of the sensors or the antennas of the array are arranged with a distribution similar to a first surface distribution;
a switching matrix with a two-dimensional array of input/output nodes, the two-dimensional array being similar to a second surface distribution different from the first surface distribution; wherein:
   each sensor or antenna of the sensor or antenna array is electrically coupled at least to the first end of the first conducting wire of one of the electronic devices of the plurality; and
   each of the input/output node is electrically coupled to the second end of the corresponding first conducting wire.

According to a further aspect, an electronic device is comprising at least one metal tube having outer and inner surfaces covered by an insulating layer, and one or more integrated circuits positioned within the metal tube.

According to an aspect, the electronic device is comprising a plurality of said metal tubes.

According to an aspect, the electronic device is comprising one or more conducting wires running inside each of the at least one metal tubes, the one or more conducting wires being coupled to the one or more integrated circuits, at least one of the conducting wires for example supplying a supply voltage to the one or more integrated circuits.

According to an aspect, the integrated circuit is an RF circuit coupled to one or more antennas.

According to an aspect, the RF circuit is an RF transceiver.

According to an aspect, the RF circuit is coupled to a plurality of antennas capable of beam forming.

According to an aspect, the insulating layer covering the outer surface of the metal tube is an SLS (selective laser sintering) material, such as nylon or polyamide.

According to an aspect, the insulating layer covering the outer surface of the metal layer comprises one or more distributed antenna pads mounted thereon, each distributed antenna pad being electrically coupled to at least one of the one or more integrated circuits.

According to an aspect, the metal tube has a substantially circular cross-section.

According to an aspect, the metal tube has a substantially rectangular cross-section.

According to an aspect, the metal tube has a cross-section width or diameter of at least 300 µm and for example of at least 1 mm, and/or of less than 5 mm, for example of substantially 5 mm, of substantially 2.5 mm or of substantially 1 mm.

According to an aspect, the metal tube is coupled to a ground voltage.

According to yet another aspect, the electronic device is further comprising one or more energy harvesting devices positioned within the metal tube and coupled to the one or more integrated circuits and/or integrated within at least one of the integrated circuits.

According to yet another aspect, there is provided a method of manufacturing an electronic device, such as the said previous electronic device, the method comprising:
positioning one or more integrated circuits within a metal tube, the metal tube having outer and inner surfaces covered by an insulating layer.

According to an aspect, the method is comprising:
forming a tubular cavity in an SLS material; and
forming or positioning the metal tube in the tubular cavity.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 is a schematic sectional view of an electronic device according to an example embodiment of the present disclosure;

FIG. 2 schematically illustrates an RF circuit;

FIG. 3 shows schematic sectional views of an electronic device according to an example embodiment of the present disclosure;

FIG. 4 is a schematic perspective view of an RF signal distribution apparatus according to an example embodiment of the present disclosure;

FIG. 5 is a schematic perspective view of a switching matrix;

FIG. 6 is a schematic sectional view of an RF signal distribution apparatus according to an example embodiment of the present disclosure;

FIG. 7 is a cross-section view schematically illustrating an RF signal distribution system according to an example embodiment of the present disclosure;

FIG. 8 is a schematic sectional view of an RF signal distribution system according to an example embodiment of the present disclosure;

FIG. 9 is a schematic perspective and sectional view of an RF signal distribution device according to an example embodiment of the present disclosure;

FIG. 10 is a perspective sectional view of an RF signal distribution system according to an example embodiment of the present disclosure;

FIG. 11 is a perspective view of an RF signal distribution system according to an example embodiment of the present disclosure;

FIG. 12 is a top view of an RF signal distribution device according to an example embodiment of the present disclosure;

FIG. 13 is a perspective view of an RF signal distribution system according to an example embodiment of the present disclosure;

FIG. 14 is a cross-section view of an RF signal distribution system according to an example embodiment of the present disclosure;

FIG. 15 is a perspective view of an RF signal distribution apparatus according to an example embodiment of the present disclosure;

FIG. 16 schematically illustrates an RF signal distribution apparatus according to an example embodiment of the present disclosure;

FIG. 17 is a perspective view of an RF signal distribution apparatus according to an example embodiment of the present disclosure;

FIG. 18 schematically illustrates an RF signal distribution apparatus according to an example embodiment of the present disclosure; and

FIG. 19 schematically illustrates an RF signal distribution apparatus according to an example embodiment of the present disclosure.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures, or to a device as orientated during normal use.

Unless specified otherwise, the expressions “around”, “approximately”, “substantially” and “in the order of” signify within 10%, and preferably within 5%.

FIG. 1 is a schematic sectional view of an electronic device 10 according to an example embodiment of the present disclosure. As will be described in more detail below, the device 10 is for example capable of being placed in opened and closed configurations, and in the example of FIG. 1, the electronic device 10 is in a closed configuration C1. The electronic device 10 for example comprises an electrically conductive structure 11 having a tubular shape. By tubular shape, it should be understood that the electrically conductive structure is formed with a hollow section, for example a circular or a rectangular section, which is prolongated, or otherwise said extruded, along a direction, which can be a curved direction such as a cable like shape. In an example, the electronic device 10 may act as a cable. In the example of FIG. 1, the electrically conductive structure 11 is of the shape of a straight tube with a circular cross-section, but it should be understood that it can be either rigid, or soft so that the electrically conductive structure 11 is twistable. The electrically conductive structure 11 for example implements a waveguide for propagating signals such as RF signals. In another non-illustrated example, the electrically conductive structure 11 has a substantially rectangular cross-section in order to adjust the wave guide property. The electrically conductive structure 11 is for example obtained by either deposition of a metal or of a conductive material like a polymer or a doped semiconductor, or by a local sintering of a powder or by a conductive tap or glue. The electrically conductive structure may be a metallic braid. In an example, the electrically conductive structure 11 has a cross-section width or diameter of at least 300 µm and for example of at least 1 mm, and/or of less than 5 mm, for example of substantially 5 mm, of substantially 2.5 mm or of substantially 1 mm. In an example, the electrically conductive structure 11 is coupled to a ground voltage in order, for example, to provide a robust shield against external radiation. The electrically conductive structure 11 for example acts as a Faraday cage for any signal passing inside so that the transmission of an RF signal in a wire arranged within the electrically conductive structure 11 has a transmission noise level as low as -100 dB.

In an example, the electronic device 10 comprises a plurality of the electrically conductive structures 11. Such a configuration improves the electrical immunity between each electronic device as regards external radiations.

The electrically conductive structure 11 for example has outer and inner surfaces covered by an insulating layer 12. In an example, the insulating layer 12 is formed of a selective laser sintering material, such as nylon or polyamide, or of a spin coated or dipped insulator like polyurethane. The insulating layer 12 may also be obtained by spraying a dissolved or molten material like a plastic. The insulating layer 12 may also be obtained by 3D printing, by lamination or by thermal shrinkage.

One or more integrated circuits 13 are positioned within the electrically conductive structure 11. In the example of FIG. 1, the insulating layer 12 for example surrounds the integrated circuits 13, reducing the risk of short circuits. In an example, the integrated circuit 13 comprises a low noise amplifier 13b and/or a power amplifier 13c, which are potentially coupled to an RF circuit such as a transceiver or a wireless communication device. The RF circuit or the wireless communication device may be arranged to receive data for controlling the integrated circuit 13 and/or transmit, to an external device, data related to the integrated circuit 13 or to the signals used by the integrated circuit 13. In an example, the RF circuit is coupled to one or more antennas or sensors. In the example of FIG. 1, antennas or sensors 151 are arranged on an external surface of the insulating layer 12. In a case in which they are antennas 151, such antennas may be arranged to either compensate for any unwanted radiation around the electronic device 10 or change the radiation scheme of the electronic device 10 on demand. In an example, such antennas 151 are capable of beam forming.

In an example where different electronic devices are envisaged, the wireless communication device of the different integrated circuits 13 may be able to communicate together. For example, in the case where several electronic devices 10 are implemented, in a first phase of operation, each different integrated circuit 13 of the electronic devices 10 may communicate between each electronic device 10 to verify for example that each integrated circuit 13 is in an operating condition. In the case where the integrated circuit 13 of one electronic device 10 is unable to work properly as detected during the first phase, the other integrated circuits 13 of the other electronic devices 10 may be able to adapt, together in conjunction, for example an inner impedance, in order to keep the radiation diagram of the antennas equivalent to the radiation diagram obtained when all the integrated circuits 13 are in working condition. Such a configuration increases the reliability of systems or apparatus in which the electronic device 10 are implemented and allows a self-healing process. In this example, an artificial intelligence (A.I) may be embedded in each integrated circuit 13 in order to obtain precise and rapid results. Such configurations may be implemented in cable test for example in order to maintain controlled or standard conditions for the signal transiting in the electronic device 10. In an example the electronic device 10 is employed for measuring 5G radiations on a surface or a volume.

In the example of FIG. 1, at least one first conducting wire 17a is coupled to the one or more integrated circuits 13. The first conducting wire 17a is for example embedded in the insulating layer 12, which reduces the risk of short circuits. The first conducting wire 17a is for example arranged to transport a first RF signal from its first end to the integrated circuits 13 when the first RF signal is applied to the first end. The first conducting wire 17a is for example arranged to transport a second RF signal from the integrated circuits 13 to a second end of the first conducting wire 17a. In an example, the integrated circuits 13 are adapted to modify the first RF signal to obtain the second RF signal in such way that the second RF signal has a different intensity or phase or voltage compared to an intensity or phase or voltage of the first RF signal. Additionally, or alternatively, the integrated circuits 13 are configured to provide impedance matching between the first and second ends of the first conducting wire 17a.

In the example of FIG. 1, a second conducting wire 17b for example extends within the electrically conductive structure 11. The second conducting wire 17b is for example coupled to the one or more integrated circuits 13 and provides a supply voltage to the integrated circuits 13 of the electronic device. The insulating layer 12 is for example arranged around the second conducting wire 17b to reduce the risk of short circuits and help reduce cross talk.

In the example of FIG. 1, third, fourth, and fifth conducting wires 17c, 17d for example extend within the electrically conductive structure 11. These conducting wires 17c, 17d, are for example coupled to the integrated circuit 13, and respectively supply a control signal and a reset signal to the integrated circuit 13. While not illustrated by a separate wire in FIG. 1, a fifth wire 17e may additionally be present, extending within the electrically conductive structure 11, and for example providing a biasing signal to the integrated circuits 13. The insulating layer 12 is for example arranged around the third, fourth, and fifth conducting wires 17c, 17d, 17e to reduce the risk of short circuits and help reduce cross talk.

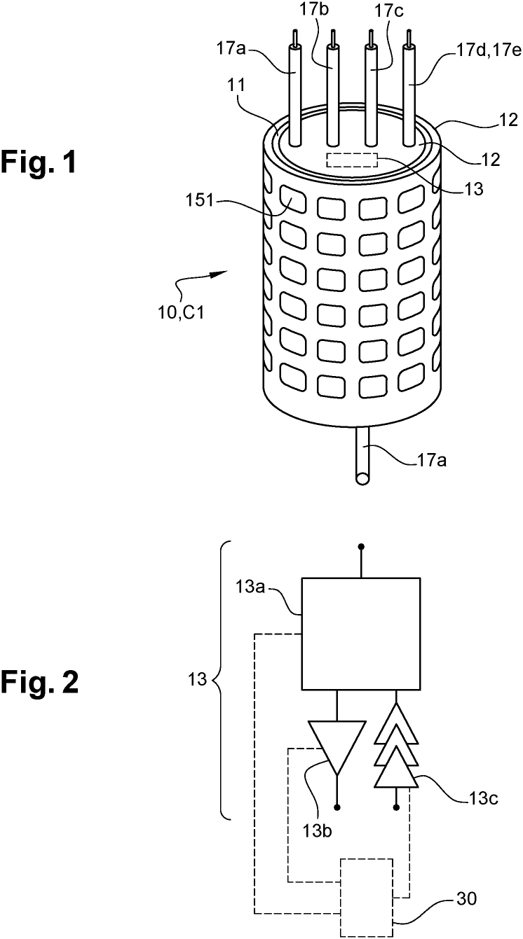

FIG. 2 schematically illustrates one of the integrated circuit 13 according to an example embodiment. In the example of FIG. 2, the integrated circuit 13 comprises a low noise amplifier 13b and/or a power amplifier 13c, which are for example coupled to an RF transceiver or a wireless communication device. These components are for example powered by an energy harvesting device 30. The energy harvesting device 30 may be positioned within the electrically conductive structure 11 and coupled to the one or more integrated circuits 13 and/or integrated within at least one of the integrated circuits 13. The use of an energy harvesting device for example to more energy efficient and autonomous device.

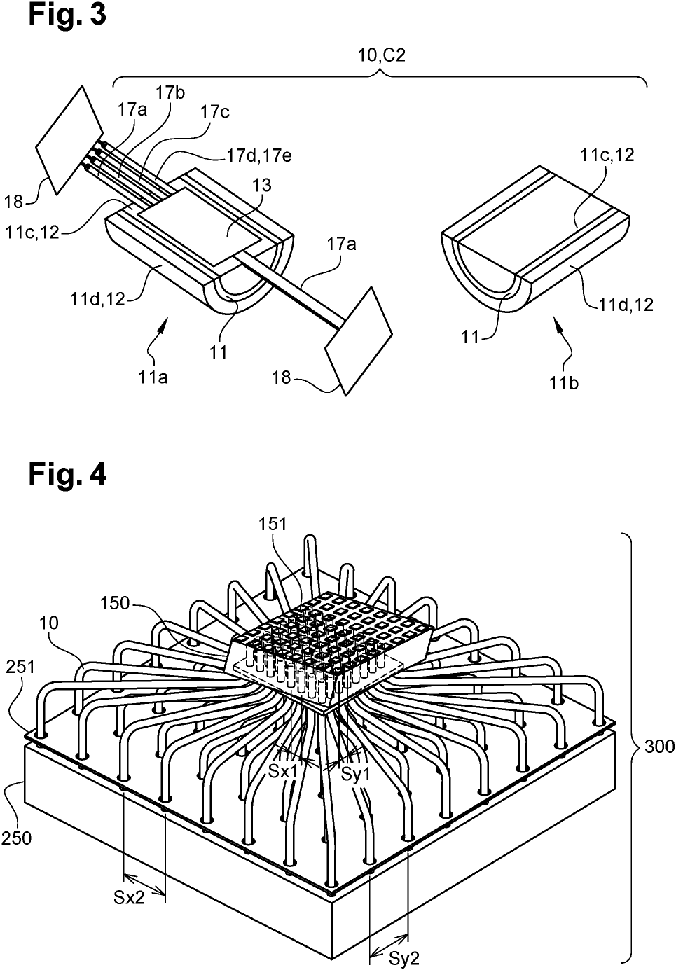

FIG. 3 is a schematic sectional view of an electronic device according to an example embodiment of the present disclosure. FIG. 3 illustrates inner and outer surface 11c, 11d of the electrically conductive structure 11 covered by the insulating layer 12.

In the example of FIG. 3, an RF connector 18 is connected to the first conducting wire 17a and another RF connector 18 is coupled to at least one of the second, third, fourth, and fifth conducting wires 17b, 17c, 17d, 17e. The electronic device 10 as such serves for example as an active RF cable.

In an example, one of the RF connectors 18 has at least a first pin electrically coupled to the electrically conductive structure 11.

In the example of FIG. 3, the electrically conductive structure 11 of the electronic device 10, and the insulating layer 12 of the inner and outer surface 11c, 11d, are divided into at least a first and a second portion 11a, 11b. In the closed configuration C1, as illustrated in FIG. 1, the first and second portion 11a, 11b are attached together. In an opened configuration C2 illustrated in FIG. 3, the first and second portion 11a, 11b are separated in such a way that the integrated circuit 13 is accessible. The opened and closed configurations C1, C2 are for example occupied sequentially. Providing such opened and closed configurations for example eases the replacement of a deficient integrated circuit 13.

In an example, the first and second portions 11a, 11b comprise a layer of a magnetic material. This allows a rapid and robust manipulation when changing the electronic device 10 between the opened and closed configurations C1, C2.

In another example, rather than a layer of magnetic material, a clip could be used to fix together the first and second parts 11a, 11b when in the closed configuration, and to release these parts 11a, 11b when changing to the opened configuration.

FIG. 4 is a perspective view of an RF signal distribution apparatus according to an embodiment of the present disclosure. The RF signal distribution apparatus 300 comprises a plurality of electronic devices 10 as described previously. The electronic devices have in this example a curved shape. The electronic devices 10 of the plurality are coupled to a sensor or antenna array 150. For example, the first end or the second end of the first conductive wire 17a of each electronic device 10 is coupled, via an RF connector for example, to each sensor or antenna 151 of the sensor or antenna array 150. At least some of the sensors or antennas 151 of the array are for example arranged with a distribution according to a first surface distribution S1. The first surface distribution S1 is for example defined by a regular pitch Sx1 in one direction and another regular pitch Sy1 in another direction, the directions of the pitches Sx1 and Sy1 for example being perpendicular directions. The first surface distribution S1 may be bidimensional or tridimensional.

The RF signal distribution apparatus 300 also for example comprises a switching matrix 250 having an array of input/output nodes or connectors 251. The array of input/output nodes or connectors 251 has a distribution according to a second surface distribution S2. The second surface distribution S2 is for example defined by a regular pitch Sx2 separating each node in one direction and another regular pitch Sy2 in another direction, the directions of the pitches Sx2 and Sy2 for example being perpendicular directions. In some embodiments, the directions of the pitches Sx1 and Sx2 are a same direction, and the directions of the pitches Sy1 and Sy2 are a same direction, and Sx2>Sx1 and/or Sy2>Sy1. The second surface distribution S2 may be bidimensional or tridimensional.

Each sensor or antenna 151 of the sensor or antenna array 150 is electrically coupled, for example, to the first end of the first conducting wire of one of the electronic devices 10 of the plurality. Each of the input/output nodes or connectors 251 is for example electrically coupled to the second end of the corresponding first conducting wire 17a. In addition, or in another example, each sensor or antenna 151 of the sensor or antenna array 150 may be electrically coupled to the electrically conductive structure 11 of the corresponding electronic devices 10 of the plurality. Each of the input/output nodes or connectors 251 may also be electrically coupled to the corresponding electrically conductive structure 11. The switching matrix 250 is for example arranged to select one or more of the input/output nodes or connectors 251. The curved shape of the electronic devices 10 for example permits RF connections between two different apparatus - the switching matrix 250 and the sensor or antenna array 150, which exhibit two different surface distributions. Since the electronic devices 10 can be curved or flexible, an array of sensors or antennas 151 can be arranged on a 3D surface and still be connected to a switching matrix or to another device, which has a different surface distribution or a different volume. This solution for example enables a mass production without having to engineer a specific device for each application.

Since every electronic device 10 of the RF signal distribution apparatus 300 for example has an electrically conductive structure 11, which acts as a Faraday cage, the transmission of an RF signal through the RF signal distribution apparatus 300 has a transmission noise level as low as -100 dB.

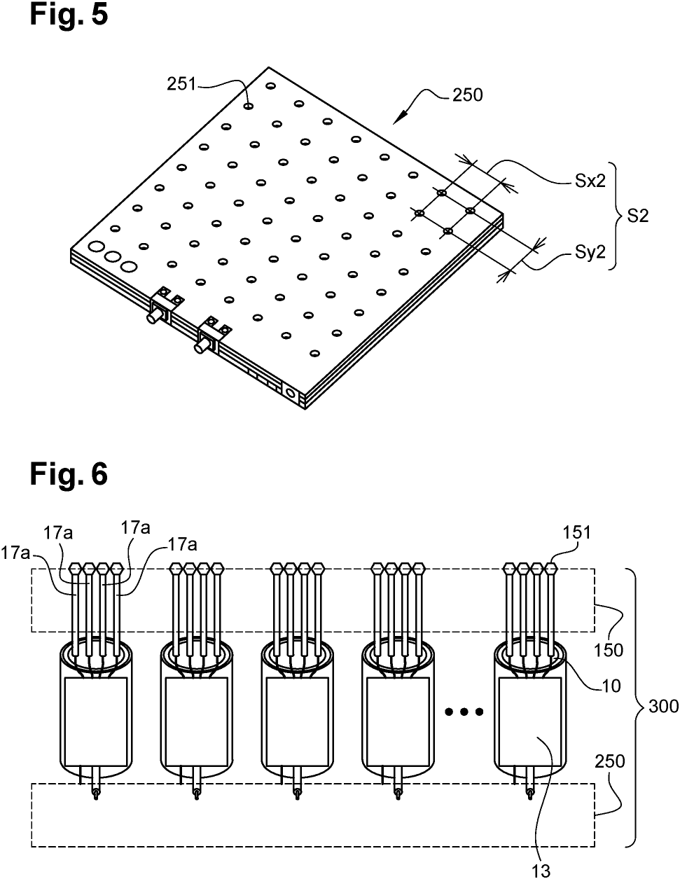

FIG. 5 is a schematic perspective view of the switching matrix 250 according to an example embodiment, having an array of input/output nodes or connectors 251. The array of input/output nodes or connectors 251 for example has a distribution similar to the second surface distribution S2. The second surface distribution S2 is, in this example, defined by a regular pitch separating each node in one direction Sx2 and the same regular pitch Sy2 in another direction. The switching matrix 250 is arranged to select one or more of the input/output nodes or connectors 251 from the array 250 and distribute, through the selected nodes, incoming or outgoing signals.

FIG. 6 illustrates a schematic view of an RF signal distribution apparatus according to an example embodiment of the present disclosure. The RF signal distribution apparatus 300 of FIG. 5 is similar to one described in relation with FIG. 4, except that each electronic device 10 comprises at least four conducting wires 17a coupled each to four different sensors or antennas 151 of the sensor or antennas array 150. Each of the four conducting wires 17a are coupled to the integrated circuit 13 of the corresponding electronic device 10. In such an example, a beam forming or a radiation reconfiguration of the antennas 151 is possible thanks to the control of the integrated circuits 13 as regards an intensity or phase or voltage of the signal passing through the different first conductive wires 17a of the electronic devices 10, and/or as regards impedance matching, and/or thanks to the interaction between the integrated circuits 13 of the various electronic devices 10.

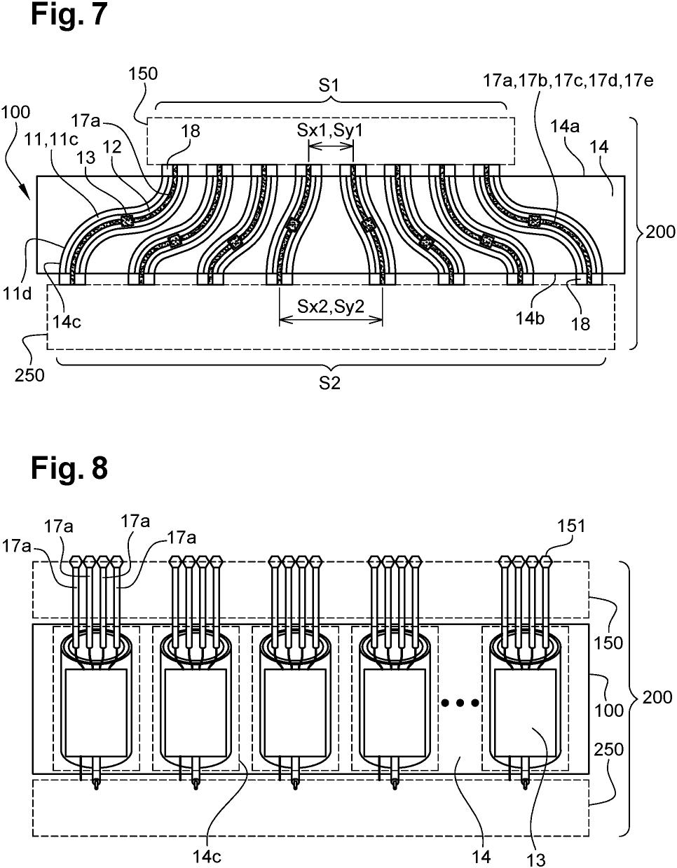

FIG. 7 is a cross-section view schematically illustrating an RF signal distribution system according to an example embodiment of the present disclosure.

The RF signal distribution system 200 comprises an RF signal distribution device 100.

In the example of FIG. 7, the RF signal distribution device 100 comprises a main body 14 having a first surface 14a, and a second surface 14b opposed to the first surface 14a. The first and second surfaces 14a, 14b may be substantially flat, or alternatively either or both could be curved or otherwise have a non-flat or 3D shape. The main body 14 is made, for example, of a material chosen between an insulator, a plastic, a metal, a material compatible with a selective sintering process, and a stacking of a plurality of layers of printed circuit board.

The RF signal distribution device 100 further comprises a plurality of cavities or tunnels 14c having a tubular shape, extending across the main body 14 from the first surface 14a to the second surface 14b. Each tunnel or cavity 14c has a first end arranged on the first surface 14a and a second end arranged on the second surface 14b. The first ends of the tunnels 14c are spaced from each other according to the first surface distribution S1. The second ends of the tunnels 14c are spaced from each other according to a second surface distribution S2 different from the first surface distribution S1. The inner surface of each tunnel 14c for example forms an electrically conductive structure 11. Otherwise said, an electrically conductive structure 11 is either formed on the inner surface of each of the tunnels or the electrically conductive structure 11 is formed by the inner surface of the tunnel 14c when the main body is electrically conductive or when at least the inner surface of the tunnels is electrically conductive.

One or more integrated circuits 13, similar to the ones described earlier, are for example positioned within each tunnel 14c of the plurality i.e. within each electrically conductive structure 11.

An insulating layer 12 is positioned between the electrically conductive structure 11 of each tunnel 14c and the integrated circuits 13.

One first conducting wire 17a is coupled to the one or more integrated circuits 13. The first conducting wire 17a is embedded in the insulating layer 12, which for example reduces risk of short circuits. The first conducting wire 17a is arranged to transport for example a first RF signal from its first end to the integrated circuits 13 when the first RF signal is applied to the first end. The first conducting wire 17a transports a second RF signal from the integrated circuits 13 to a second end of the first conducting wire 17a. In an example, the integrated circuits 13 are adapted to provide impedance matching and/or to modify the first RF signal to obtain the second RF signal in such way that the second RF signal has a different intensity or phase or voltage compared to an intensity or phase or voltage of the first RF signal.

In the example of FIG. 7, a second conducting wire 17b for example extends within the electrically conductive structure 11. The second conducting wire 17b is for example coupled to the one or more integrated circuits 13 and provides respectively a supply voltage to the integrated circuits 13 of the electronic device. The insulating layer 12 is for example arranged around the second conducting wire 17b to reduce the risk of short circuits and also to reduce cross talk.

In the example of FIG. 7, third, fourth, and fifth conducting wires 17c, 17d, 17e for example extend within the electrically conductive structure 11. The third, fourth, and fifth conducting wires 17c, 17d, 17e are for example coupled to the integrated circuit 13, and for example respectively supply a control signal, a reset signal and a bypass signal to the integrated circuit 13. The insulating layer 12 is for example arranged around the third, fourth, and fifth conducting wires 17c, 17d, 17e to reduce the risk of short circuits and also to reduce cross talk.

In another example, one of the electronic devices 10 is formed or positioned within each tunnel 14c of the plurality. In this example, the first, second, third, fourth and fifth conductive wires 17a, 17b, 17c, 17d, 17e, the insulator layer 12 and the integrated circuit 13 are for example comprised in the electronic device 10 that is positioned within the tunnel 14c. In this configuration, a double Faraday cage is formed by the electrically conductive structure of the inner surface of the tunnel and by the electrically conductive structure of the electronic device 10. This leads to an RF transmission through the RF signal distribution device 100 with a noise level that is for example as low as -100 dB.

A method of manufacturing the RF signal distribution device 100 for example comprises forming, in the main body 14, the plurality of tunnels 14c with their inner surfaces forming the electrically conductive structures 11. This may be performed for example by a molding process, a 3D printing process or a stacking of a plurality of printed circuit board layers.

In an additional example, the method of manufacturing the RF signal distribution device 100 for example comprises positioning or forming the insulating layer 12 at least between the electrically conductive structure 11 of each tunnel 14c and at least part of the integrated circuits 13 positioned within each tunnel 14c of the plurality.

In an additional example, the method of manufacturing the RF signal distribution device 100 for example comprises positioning or forming the insulating layer 12 between the electrically conductive structure 11 of each tunnel 14c and at least part of the first, second, third, fourth and fifth conductive wires 17a, 17b, 17c, 17d, 17e.

The RF signal distribution system 200 for example further comprises a sensor or antenna array 150 similar to one described earlier.

The RF signal distribution system 200 for example further comprises a switching matrix 250 similar to one described earlier.

The RF signal distribution device 100 of the RF signal distribution system 200 is for example arranged between the sensor or antenna array 150 and the switching matrix 250 in such way that each sensor or antenna 151 of the sensor or antenna array 150 is electrically coupled to the first end of the first conducting wire 17a of one of the tunnels of the RF signal distribution device 100. An RF connector 18 may be implemented to realize this connection. Each input/output node or connector 251 of the switching matrix 250 is for example electrically coupled to the second end of the corresponding first conducting wire 17a. An RF connector 18 may be used to realize this connection.

In an example, each sensor or antenna 151 of the sensor or antenna array 150 is aligned with a corresponding first end of one of the tunnels of the RF signal distribution device 100; and the input/output nodes or connectors 251 of the two-dimensional array are aligned each with the second end of the corresponding tunnel.

The curved shape of the tunnels and the corresponding electrically conductive structure for example permits RF connections between two different apparatus - the switching matrix 250 and the sensor or antenna array 150, which exhibit two different surface distribution S1 and S2.

This solution for example enables mass production of switching matrices without having to engineer a specific device with a different pitch for each application. Since every electronic device 10 of the RF signal distribution system 200 has an electrically conductive structure 11, which acts as a Faraday cage, the transmission of an RF signal through the RF signal distribution system 200 for example has a transmission noise level as low as -100 dB.

FIG. 8 is a schematic view of an RF signal distribution system according to an example embodiment of the present disclosure. The RF signal distribution system 200 of FIG. 8 is similar to the RF signal distribution apparatus 300 described in relation with FIG. 6, except that each electronic device 10 is positioned within an electrically conductive structure 11 formed on an inner surface of a tunnel 14c of the plurality of tunnels of the main body 14. In this configuration, a double Faraday cage is formed by the electrically conductive structure of the inner surface of the tunnels 14c and by the electrically conductive structure of each of the electronic device 10. This for example leads to an RF transmission noise level as low as -100 dB. In a such example, a beam forming or a radiation reconfiguration of the antennas 150 is possible thanks to the control of the integrated circuits 13 as regards intensity or phase or voltage of the signal passing through the different first conductive wires 17a of the electronic devices 10, and/or as regards impedance matching, and/or thanks to the interaction between the integrated circuits 13 of the different electronic devices 10.

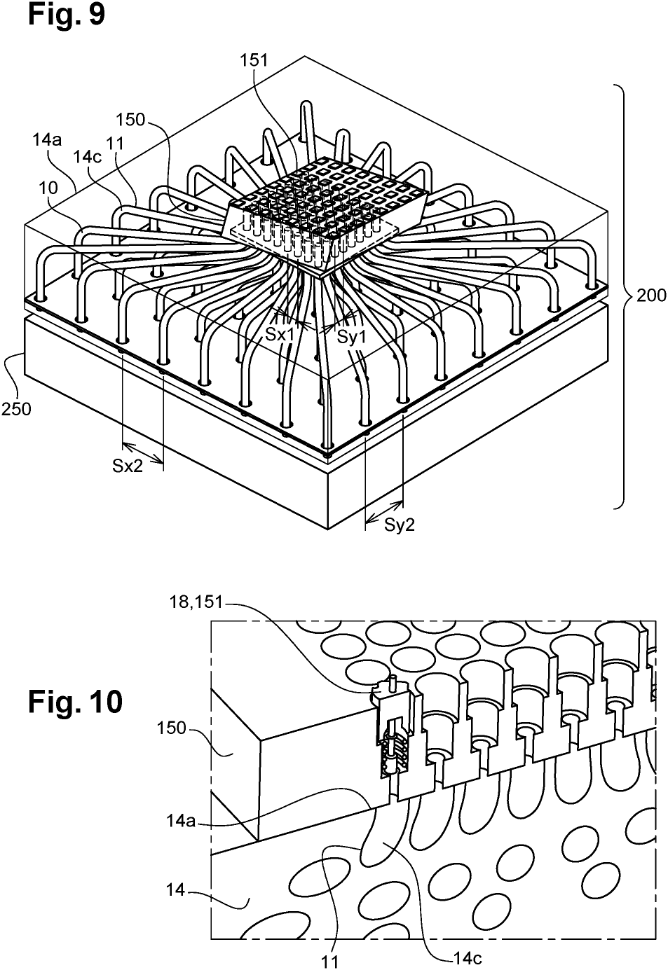

FIG. 9 is a schematic perspective view of an RF signal distribution system according to an example embodiment of the present disclosure. The RF signal distribution system 200 of FIG. 9 is similar to the RF signal distribution apparatus 300 described in relation with FIG. 4, except that each electronic device 10 is positioned within an electrically conductive structure 11 formed on an inner surface of a tunnel 14c of a plurality of tunnels of a main body 14. In this configuration, a double Faraday cage is formed by the electrically conductive structure of the inner surface of the tunnels 14c and by the electrically conductive structure of each of the electronic device 10. This leads for example to an RF transmission noise level as low as -100 dB.

FIG. 10 is schematic sectional view of an RF signal distribution device 100 according to an example embodiment of the present disclosure. The sensor or antenna array 150 is positioned on the first surface 14a of the main body 14 of the RF signal distribution device 100 in such a way that the first ends of each tunnel 14c are aligned with the RF connectors 18 coupled to the sensor or antenna 151 of the sensor or antenna array 150. In this example, the tunnels 14c of the main body 14 are curved to allow an RF transmission between the RF connectors 18 coupled to the sensors or antennas 151 and spaced with a certain pitch or surface distribution to a non-illustrated switching matrix having a different pitch or surface distribution.

FIG. 11 is a perspective view of an RF signal distribution system 200 according to an example embodiment of the present disclosure. The RF signal distribution system 200 of FIG. 11 is similar to the RF signal distribution system 200 described in relation with FIG. 9. An RF signal may be transmitted from the sensor or antenna array 150 exhibiting a regular pitch to the switching matrix 250, which has a different pitch and which can be produced at large scale thanks to the RF distribution device 100 linking the sensors or antenna array 150 and the switching matrix 250.

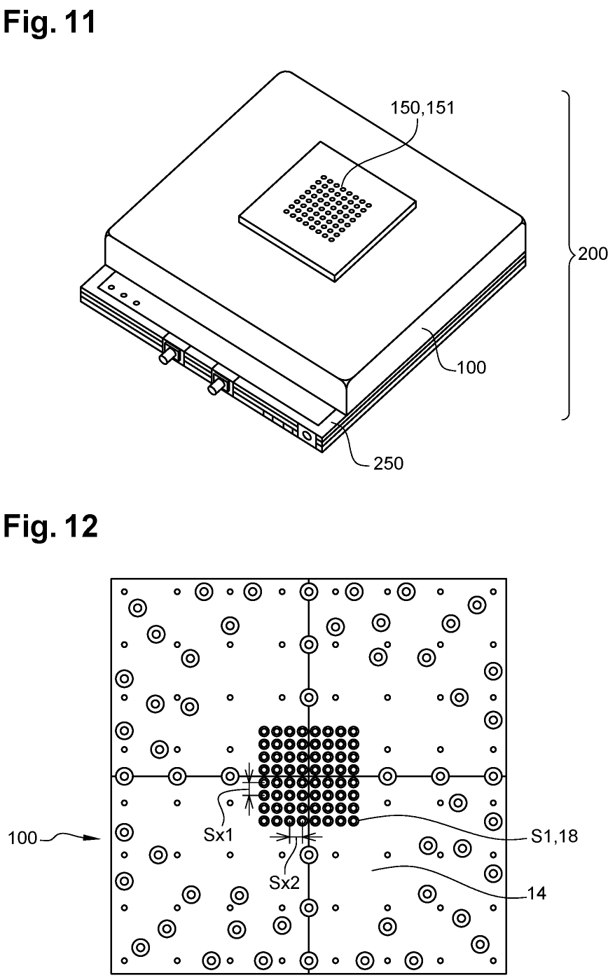

FIG. 12 is a top view of an RF signal distribution device 100 according to an example embodiment of the present disclosure. In this example, RF connectors 18, corresponding to a sensor or antennas array, are coupled to the RF signal distribution device 100. The main body of the RF signal distribution device 100 is for example made of a stacking of different PCB boards. The main body 14 is for example divided into four parts, which can be disassembled or assembled together or with other similar parts to obtain a larger global main body 14 if necessary. The four parts of the main body 14, once assembled, for example define tunnels (non-illustrated) with electrically conductive structures (non-illustrated) formed on their inner surface.

FIG. 13 is a sectional view of an RF signal distribution system 200 according to an example embodiment of the present disclosure. In this example, the RF signal distribution system 200 is similar to the RF signal distribution system 200 of FIG. 7 except that the plurality of tunnels 14c and the corresponding electrically conductive structure 11 are formed by stacking several printed circuit boards.

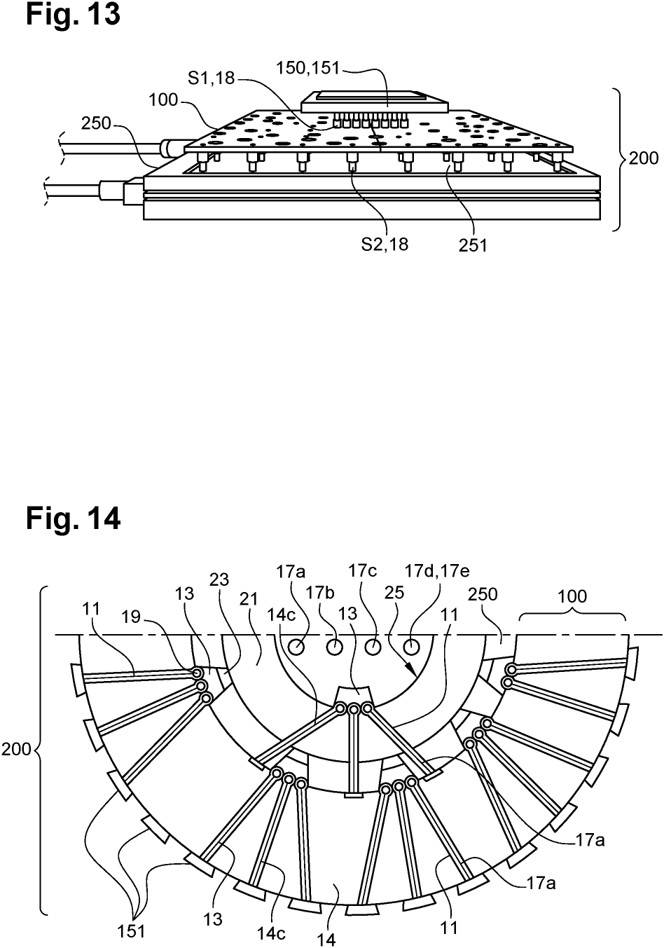

FIG. 14 is a cross-section view illustrating an RF signal distribution system 200 according to an example embodiment of the present disclosure. For example, the cross-section of FIG. 14 corresponds to a cross-section of part of the device 10 of FIG. 1 passing through a row of the antennas or sensors 151. As such, the four conducting wires 17a, 17b, 17c and 17d are illustrated, a fifth conducting wire 17e also being present in some embodiments. However, in alternative embodiments, no such wires are present in the RF distribution system 200 of FIG. 14.

In the example of FIG. 14, the switching matrix 250 and the sensor or antenna array 150 have curved and concentric surfaces. The switching matrix 250 may have different levels with integrated circuits. The RF signal distribution device 100 has a main body 14 through which straight tunnels 14c are arranged. The first surface distribution S1 of the sensors or antenna 151 is made of a regular pitch along the curved surface of the main body 14. The second surface distribution of input/output nodes or connectors of the switching matrix are labelled 19 and are symbolized by black dots and the nodes are for example grouped three by three. In the embodiment of FIG. 14, the switching matrix is implemented by one or more of the integrated circuits 13, which are for example sandwiched between the main body 14 and an inner body 21. The integrated circuits 13 are for example mounted on a layer 23 contacting the inner body 21, the layer 23 for example providing insulation and/or shielding. In some embodiments, the integrated circuits 13 are coupled to one or more of the conducting wires 17a to 17e.

Each tunnel 14c of the main body 14 is aligned between one of the input/output nodes 19 and one of the senor or antennas 151. Each tunnel 14c has an electrically conductive structure 11 formed on its inner surface. In this configuration, a Faraday cage is for example formed by the electrically conductive structure of the inner surface of the tunnel and by the electrically conductive structure of the electronic device 10. This for example leads to an RF transmission through the RF signal distribution device 100 with a noise level as low as -100 dB. A such configuration is compact and it enables a beam forming via the antennas 151, which may be controlled by the different integrated circuits 13. It also for example allows the radiation diagram of the senor or antenna array 150 to be modified on demand.

Furthermore, in some embodiments, one or more integrated circuits 13 are positioned on an inner surface 25 of the inner body 21, and for example communicate with the integrated circuits 13 mounted on the main body 14 via one or more further electrically conductive structures 11 formed on the inner surface of further tunnels 14c traversing the inner body 21 and/or via one or more conductive wires 17a passing through these tunnels.

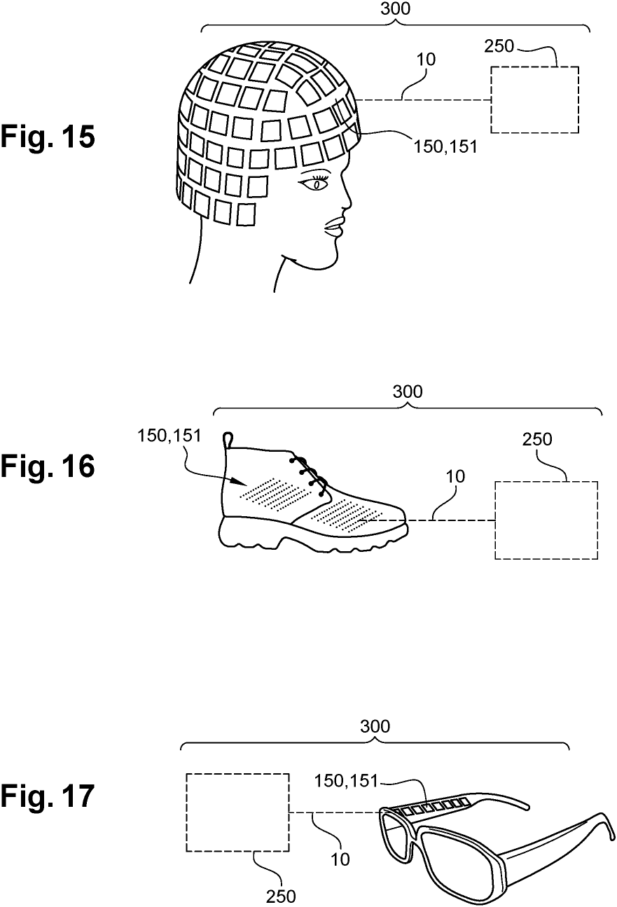

FIG. 15 is a schematic view of an RF signal distribution apparatus 300 according to an example embodiment of the present disclosure. In this example, the sensor or antenna array 150 is applied on a curved surface surrounding a head of a person or a dummy in order to measure and/or apply RF radiations all around the head. The sensor or antenna array 150 is for example coupled to the switching matrix 250 via different electronic devices 10 as described previously. Thanks to flexibility of the electronic devices 10, each electronic device 10 may be coupled to a sensor or an antenna 151 on a precise 3D surface around the head.

FIG. 16 is a schematic view of an RF signal distribution apparatus 300 according to another example embodiment of the present disclosure. The RF signal distribution apparatus 300 of FIG. 16 is similar to the one of FIG. 15, except that the sensor or antenna array 150 is applied on a curved surface of a shoe.

FIG. 17 is a schematic view of an RF signal distribution apparatus 300 according to an example embodiment of the present disclosure. The RF signal distribution apparatus 300 of FIG. 17 is similar to the one of FIGS. 15 and 16, except that the sensor or antenna array 150 is applied on a surface of a pair of glasses, goggles or sunglasses.

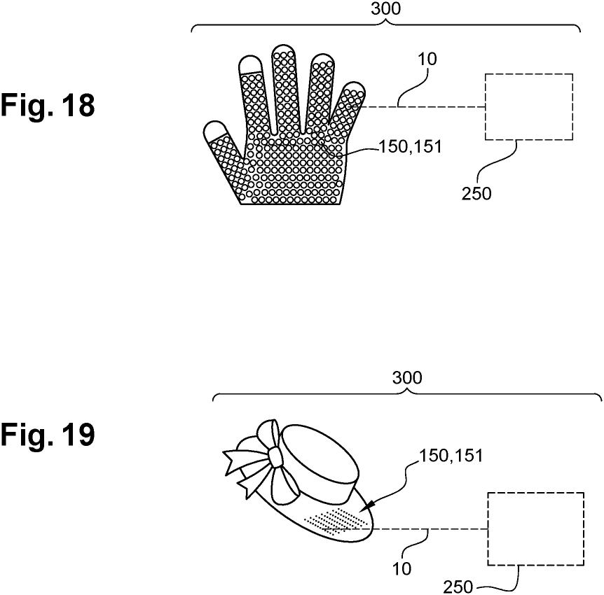

FIG. 18 is a schematic view of an RF signal distribution apparatus 300 according to an example embodiment of the present disclosure. The RF signal distribution apparatus 300 of FIG. 18 is similar to the one of FIGS. 15 to 17, except that the sensor or antenna array 150 is applied on a surface of a glove.

FIG. 19 is a schematic view of an RF signal distribution apparatus 300 according to an example embodiment of the present disclosure. The RF signal distribution apparatus 300 of FIG. 17 is similar to the one of FIGS. 15 to 18, except that the sensor or antenna array 150 is applied on a surface of a hat.

Various embodiments and variants have been described. Those skilled in the art will understand that certain features of these embodiments can be combined and other variants will readily occur to those skilled in the art. For example, the sensor or antenna array 150 of the RF signal distribution apparatus 300 may be applied on diverse surfaces such as curved surfaces where RF radiations may be applied or measured.

Finally, the practical implementation of the embodiments and variants described herein is within the capabilities of those skilled in the art based on the functional description provided hereinabove.

1-34. (canceled)

35. An electronic device, comprising:
an electrically conductive structure with a tubular shape having outer and inner surfaces covered by an insulating layer; and
one or more integrated circuits positioned within the electrically conductive structure.

36. The electronic device of claim 35, wherein:
the electrically conductive structure and the insulating layer comprise a first and a second portion arranged to assume sequentially a first configuration where the first and second portions are attached together and a second configuration where the first and second portions are separated in such a way that the one or more integrated circuits are accessible,
the first and second portions comprise a layer of a magnetic material for attaching the first and second portions together, and
the electronic device comprises a plurality of said electrically conductive structures.

37. The electronic device of claim 35, wherein:
the insulating layer is positioned between the electrically conductive structure and at least a part of one or more conducting wires extending inside the electrically conductive structure,
the insulating layer covering the outer surface of the electrically conductive structure is made of a selective laser sintering material, such as nylon or polyamide, and
the insulating layer covering the outer surface of the electrically conductive structure comprises one or more distributed antenna pads mounted thereon, each distributed antenna pad being electrically coupled to at least one of the one or more integrated circuits.

38. The electronic device of claim 35, wherein the electrically conductive structure has a cross-section width or diameter of at least 300 µm and of less than 5 mm, the electrically conductive structure being coupled to a ground voltage.

39. The electronic device of claim 35, further comprising one or more energy harvesting devices positioned within the electrically conductive structure and coupled to or integrated within the one or more integrated circuits.

40. An RF signal distribution device, comprising:
a main body having a first surface and a second surface opposed to the first surface; and
a plurality of tunnels extending across the main body from the first surface to the second surface, each tunnel having a first end arranged on the first surface and a second end arranged on the second surface, wherein:
the first ends of the tunnels are spaced from each other according to a first surface distribution,
the second ends of the tunnels are spaced from each other according to a second surface distribution different from the first surface distribution, and
an inner surface of each tunnel forms an electrically conductive structure.

41. The RF signal distribution device of claim 40, wherein the main body is made of a material chosen between an insulator, a plastic, a metal, a selective laser sintering material, and a stacking of different layers of printed circuit board.

42. The RF signal distribution device of claim 40, further comprising an insulating layer positioned between the electrically conductive structure of each tunnel and at least part of one or more integrated circuits positioned within each tunnel, the insulating layer being positioned between the electrically conductive structure and at least a part of one or more conducting wires extending inside each electrically conductive structure.

43. The RF signal distribution device of claim 42, wherein:
the first surface distribution has a first regular pitch arrangement, and
the second surface distribution has a second regular pitch arrangement different from the first regular pitch arrangement.

44. The RF signal distribution device of claim 42, wherein:
at least one conducting wire of the one or more conducting wires is coupled to the one or more integrated circuits and is adapted to:
transport a first RF signal from a first end of the at least one conducting wire to the one or more integrated circuits, and
transport a second RF signal from the one or more integrated circuits to a second end of the at least one conducting wire,
the one or more integrated circuits is adapted to provide impedance adapting,
the RF signal distribution device further comprises an RF connector, the RF connector comprising at least a first pin electrically coupled to the electrically conductive structure and at least a second pin coupled to either the first or second end of the at least one conductive wire,
the one or more integrated circuits comprise at least one of an RF circuit and an RF transceiver coupled to one or more antennas, and
the at least one of the RF circuit and the RF transceiver coupled to the one or more antennas is capable of beam forming.

45. The RF signal distribution device of claim 44, wherein at least one further conducting wire runs inside each electrically conductive structure, the at least one further conducting wire being coupled to the one or more integrated circuits and providing to the one or more integrated circuits one or more of: a supply voltage, a control signal, a reset signal, and a bypass signal.

46. The RF signal distribution device of claim 44, wherein each integrated circuit among the one or more integrated circuits comprises a wireless communication device arranged to at least one of:
receive data for controlling the integrated circuit, and
transmit, to an external device such as another electronic device, data related to at least one of the one or more integrated circuits, the first RF signal, and the second RF signal.

47. The RF signal distribution device of claim 44 in an RF signal distribution system, the RF signal distribution system comprising:
a sensor or antenna array where at least part of sensors or antennas of the sensor or antenna array are arranged with a distribution similar to the first surface distribution of the RF signal distribution device; and
a switching matrix with a two-dimensional array of input/output nodes, the two-dimensional array being similar to the second surface distribution of the RF signal distribution device, wherein the RF signal distribution device is arranged between the sensor or antenna array and the switching matrix in such a way that:
each sensor or antenna of the sensor or antenna array is electrically coupled to the first end of the at least one conducting wire of the RF signal distribution device, and
each of the input/output nodes is electrically coupled to the second end of the at least one conducting wire.

48. The RF signal distribution system of claim 47, wherein:
each sensor or antenna of the sensor or antenna array is aligned with a corresponding first end of one of the tunnels of the RF signal distribution device, and
the input/output nodes of the two-dimensional array are aligned each with the second end of the corresponding tunnel.

49. The RF signal distribution device of claim 44 in an RF signal distribution apparatus, the RF signal distribution apparatus comprising:
a plurality of RF signal distribution devices including the RF signal distribution device;
a sensor or antenna array where at least part of sensors or antennas of the sensor or antenna array are arranged with a distribution similar to the first surface distribution of the RF signal distribution device; and
a switching matrix with a two-dimensional array of input/output nodes, the two-dimensional array being similar to the second surface distribution of the RF signal distribution device and different from the first surface distribution, wherein:
each sensor or antenna of the sensor or antenna array is electrically coupled at least to the first end of the at least one conducting wire of the RF signal distribution device, and
each of the input/output nodes is electrically coupled to the second end of the at least one conducting wire.

50. A method of manufacturing an electronic device, the method comprising:
providing one or more integrated circuits;
forming an insulating layer surrounding at least a part of the one or more integrated circuits; and
forming an electrically conductive structure with a tubular shape in such a way that the insulating layer covers an inner surface and an outer surface of the electrically conductive structure.

51. A method of manufacturing an RF signal distribution device, comprising:
preparing, in a main body having a first surface and a second surface, a plurality of tunnels extending across the main body from the first surface to the second surface, wherein:
each tunnel has a first end arranged on the first surface and a second end arranged on the second surface,
an inner surface of each tunnel forms an electrically conductive structure,
the first ends of each of the of tunnels is spaced from each other according to a first surface distribution, and
the second ends of each of the tunnels is spaced from each other according to a second surface distribution different from the first surface distribution.

52. The method of claim 51, wherein the plurality of tunnels in the main body are obtained with either a selective laser sintering process, a molding process, a 3D printing process, or a stacking of a plurality of printed circuit board layers.

53. The method of claim 51, further comprising:
positioning or forming an insulating layer at least between the electrically conductive structure of each tunnel and at least part of one or more integrated circuits positioned within each electrically conductive structure; and
positioning or forming the insulating layer between the electrically conductive structure of each tunnel and at least part of one or more conducting wires running inside each electrically conductive structure.

54. The method of claim 51, further comprising forming or positioning an electronic device within each electrically conductive structure, wherein each electronic device comprises one or more integrated circuits.
